(19) United States
(12) Patent Application Publication
(10) Pub. No.: US 2026/0371806 A1
(43) Pub. Date: Nov. 19, 2026

(54) METHODS FOR FORMING AN LED PACKAGE WITH AN LED COLOR MIXER

(71) Applicant: CreeLED, Inc., Durham, NC (US)

(72) Inventors: Michael Check, Holly Springs, NC (US); Steven Wuester, Salemburg, NC (US); Nikolas Hall, Durham, NC (US)

(21) Appl. No.: 19/210,238

(22) Filed: May 16, 2025

(51) Int. Cl. H10H 29/01; H10H 29/24; H10H 29/85; H10H 29/854

(52) U.S. Cl. CPC H10H 29/0362; H10H 29/0364; H10H 29/24; H10H 29/854; H10H 29/857

(57) ABSTRACT

Light-emitting diode (LED) devices and, more particularly, methods for forming an LED package with an LED color mixer with a continuous seal are disclosed. The LED color mixer can be an inverted color mixer where light exits the LED package opposite the side of the LED package from which the light is emitted by two or more LED chips, passing through a lead frame on which the LED chips are mounted. To form the LED package, a flexible support element can be inserted into a mold, and the inverted color mixer and fill material of a housing can be formed within the mold. The housing of the LED package, after being formed in the mold, can be removed, and after plastic removal, an epoxy shell can be formed around the housing.

### FIELD OF THE DISCLOSURE

The present disclosure relates to light-emitting diode (LED) devices, and more particularly to methods for forming an LED package with an LED color mixer with a continuous seal.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs continue to enable a variety of new LED display and general illumination applications.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that provide mechanical support, electrical connections, and encapsulation for LED emitters. As LED technology continues to be developed for ever-evolving modern applications, challenges exist in keeping up with operating demands for LED packages and related elements of LED packages.

LED packages that contain more than one LED chip, particularly LED packages with different colored LED chips can have far field patterns (FFPs) that have different color intensities depending on the angle at which the LED package is viewed. This is detrimental to the color uniformity of LED displays and other applications as the color is observed to change with viewing angle.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to methods for forming an LED package with a LED color mixer with a continuous seal. The LED color mixer can be an inverted color mixer where light exits the LED package opposite the side of the LED package from which the light is emitted by two or more LED chips, passing through a lead frame on which the LED chips are mounted. To form the LED package, a flexible support element can be inserted into a mold, and the inverted color mixer and fill material of a housing can be formed within the mold. The housing of the LED package, after being formed in the mold, can be removed, and after plastic removal, an epoxy shell can be formed around the housing.

In one aspect, a method for forming an LED package includes inserting one or more LED chips mounted on a flexible support element into a mold, wherein the flexible support element comprises a plurality of flexible electrical traces in contact with electrodes of the one or more LED chips , and wherein electrical contact pads of the flexible electrical traces extend out of the mold and folded portions of the flexible support element within the mold form a housing of the LED package. The method also includes forming a transparent dome over the one or more LED chips in the housing of the LED package, filling the housing of the LED package with a fill material, and folding the electrical contact pads over the fill material. The method also includes removing the housing of the LED package from the mold, removing plastic portions of the flexible support element, and forming an epoxy shell around the housing of the LED package, while leaving the electrical contact pads exposed.

In an embodiment, the removing plastic portions of the flexible support element comprises at least one of etching the plastic portions or performing plasma ashing.

In an embodiment, the transparent dome and the epoxy shell comprise the same material.

In an embodiment, the one or more LED chips are adjacent to an opposite face of the LED package as a face that comprises the electrical contact pads.

In an embodiment, light is emitted from the LED package through gaps in the flexible electrical traces out of a face adjacent to the LED chips.

In an embodiment, the transparent dome and the fill material form an inverted color mixer within the housing of the LED package.

In an embodiment, the fill material is a white epoxy.

In an embodiment, the removing the housing of the LED package from the mold comprises attaching a removal element with an adhesive surface to the electrical contact pads and pulling the removal element away from the mold to remove the housing of the LED package from the mold.

In an embodiment, the flexible support element comprises an etch stop layer, wherein the one or more LED chips and the flexible electrical traces are between the etch stop layer and plastic portions of the flexible support element.

In an embodiment, the etch stop layer is Al₂O₃.

In an embodiment, each respective electrode of the one or more LED chips is electrically connected to two or more electrical contact pads.

In another aspect, a method for forming an LED package includes inserting one or more LED chips mounted on a flexible support element into a mold, wherein the flexible support element comprises a plurality of flexible electrical traces in contact with electrodes of the one or more LED chips, and wherein electrical contact pads of the flexible electrical traces extend out of the mold and folded portions of the flexible support element within the mold form a housing of the LED package. The method also includes forming an inverted color mixer over the one or more LED chips in the housing of the LED package, wherein the inverted color mixer comprises a transparent dome over the one or more LED chips and a fill material surrounding the transparent dome, wherein light emitted by the one or more LED chips exits the inverted color mixer via gaps in the flexible electrical traces. The method also includes folding the electrical contact pads over the fill material, removing the housing of the LED package from the mold, removing plastic portions of the flexible support element, and forming an epoxy shell around the housing of the LED package, while leaving the electrical contact pads exposed.

In an embodiment, the removing plastic portions of the flexible support element comprises at least one of etching the plastic portions or performing plasma ashing.

In an embodiment, the transparent dome and the epoxy shell comprise the same material.

In an embodiment, the fill material is a white epoxy.

In an embodiment, the one or more LED chips are adjacent to an opposite face of the LED package as a face that comprises the electrical contact pads.

In an embodiment, the removing the housing of the LED package from the mold comprises attaching a removal element with an adhesive surface to the electrical contact pads and pulling the removal element away from the mold to remove the housing of the LED package from the mold.

In an embodiment, the flexible support element comprises an etch stop layer, wherein the one or more LED chips and the flexible electrical traces are between the etch stop layer and plastic portions of the flexible support element.

In an embodiment, the etch stop layer is Al₂O₃.

In an embodiment, each respective electrode of the one or more LED chips is electrically connected to two or more electrical contact pads.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-sectional view of a flexible support element that comprises flexible electrical traces and a plurality of light-emitting diode (LED) chips according to an embodiment of the present disclosure.

FIG. 2 is a top-down view of the flexible support element of FIG. 1 according to an embodiment of the present disclosure.

FIG. 3 is a top-down view of a tray of molds according to an embodiment of the present disclosure.

FIG. 4 is a cross-sectional view of the flexible support element inserted into a mold in a step in the manufacturing process of an LED package according to an embodiment of the present disclosure.

FIG. 5 is a cross-sectional view of the mold and flexible support element with an epoxy dome installed within the housing of the LED package according to an embodiment of the present disclosure.

FIG. 6 is a cross-sectional view of the mold and flexible support element with fill material added according to an embodiment of the present disclosure.

FIG. 7 is a cross-sectional view of the mold and flexible support element with the electrical contact pads folded over the housing of the LED package according to an embodiment of the present disclosure.

FIG. 8 is a cross-sectional view of a removal element with an adhesive surface attached to the electrical contact pad according to an embodiment of the present disclosure.

FIG. 9 is a cross-sectional view of the LED package after being removed from the mold according to an embodiment of the present disclosure.

FIG. 10 is a cross-sectional view of the LED package after removing the plastic from the flexible support element according to an embodiment of the present disclosure.

FIG. 11 is a cross-sectional view of the LED package with an epoxy shell according to an embodiment of the present disclosure.

FIG. 12 is a top-down view of the LED package and the electrical contact pads according to an embodiment of the present disclosure.

FIG. 13 is a cross-sectional view of another embodiment of the flexible support element according to an embodiment of the present disclosure.

FIG. 14 is a top-down view of another embodiment of the flexible support element according to an embodiment of the present disclosure.

FIG. 15 is a top-down view of the LED package and electrical contact pads according to the embodiment from FIG. 14 according to an embodiment of the present disclosure.

FIG. 16 is a top-down view of another embodiment of the flexible support element according to an embodiment of the present disclosure.

FIG. 17 is a top-down view of the LED package and electrical contact pads according to the embodiment from FIG. 16 according to an embodiment of the present disclosure.

FIG. 18 is a flow chart of a method for forming an LED package according to an embodiment of the present disclosure.

FIG. 19 is a schematic diagram of a portion of an LED device, such as a display screen including a large number of LED packages, according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to methods for forming an LED package with a LED color mixer with a continuous seal. The LED color mixer can be an inverted color mixer where light exits the LED package opposite the side of the LED package from which the light is emitted by two or more LED chips, passing through a lead frame on which the LED chips are mounted. To form the LED package, a flexible support element can be inserted into a mold, and the inverted color mixer and fill material of a housing can be formed within the mold. The housing of the LED package, after being formed in the mold, can be removed, and after removing the plastic of the flexible support element, an epoxy shell can be formed around the housing. The interface of the polymer shell (e.g., epoxy) and the non-polymer components (metallic electrical contact pads) are on opposite sides of the LED package, which reduces the likelihood of LED failure compared to when the configuration is reversed where the interface is near the LED chips in traditional packaging designs.

Before delving into specific details of various aspects of the present disclosure, an overview of elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements.

The active LED structure can be fabricated from different material systems, with some material systems being Group III nitride-based material systems. Group III nitrides refer to semiconductor compounds formed between nitrogen (N) and elements in Group III of the periodic table, usually aluminum (Al), gallium (Ga), and/or indium (In) in the form of binary, ternary, and/or quaternary compounds. Other material systems include organic semiconductor materials, and other Group III-V systems such as gallium phosphide (GaP), gallium arsenide (GaAs), and related compounds. The active LED structure may be grown on a growth substrate that can include many materials, such as sapphire, silicon carbide (SiC), silicon, aluminum nitride (AlN), and GaN.

Different embodiments of the active LED structure can emit different wavelengths of light depending on the composition of the active layer. In certain embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B light is typically defined as a peak wavelength range from 280 nm to 315 nm, and UV-C light is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

Aspects of the present disclosure are applicable to multiple-chip LED packages where multiple LED chips are arranged within a common package. For multiple-chip examples, LED packages may include a red-emitting LED chip, a green-emitting LED chip, and a blue-emitting LED chip such that the LED package may be positioned as a pixel in an LED display. In other embodiments, aspects of the present disclosure may be applicable to other LED packages, such as those that include one or more LED chips with a recipient lumiphoric material that converts at least a portion of light generated from the one or more LED chips to a different wavelength.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphoric material receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Cai-x-ySrxEuyAlSiN3) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations.

As used herein, a layer or region of a light-emitting device may be considered to be "transparent" when at least 80% of emitted radiation that impinges on the layer or region emerges through the layer or region. Moreover, as used herein, a layer or region of an LED is considered to be "reflective" or embody a “mirror” or a "reflector" when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective).

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a support structure of an LED package such that the anode and cathode connections are on a face of the LED chip that is opposite the support structure. In this configuration, wire bonds may be used to provide electrical connections with the anode and cathode connections. In other embodiments, a lateral geometry LED chip may be flip-chip mounted on a surface of a support structure of an LED package such that the anode and cathode connections are on a face of the active LED structure that is adjacent to the support structure. In this configuration, electrical traces or portions of a lead frame may be provided with the support structure for providing electrical connections to the anode and cathode connections of the LED chip. In a flip-chip configuration, the active LED structure is configured between the substrate of the LED chip and the support structure for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a lead frame structure. Lead frame structures are typically at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, polyamide, polyimide, polyethylene terephthalate, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. Encapsulant materials may also form lenses that direct light in desired emission directions and/or patterns. In certain embodiments, one or more lumiphoric materials, such as phosphor particles, may be integrated or otherwise embedded within the encapsulant material.

Light-altering materials may be arranged within LED packages, such as within housings and/or within portions of recesses thereof, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque or black color for absorbing light and increasing contrast.

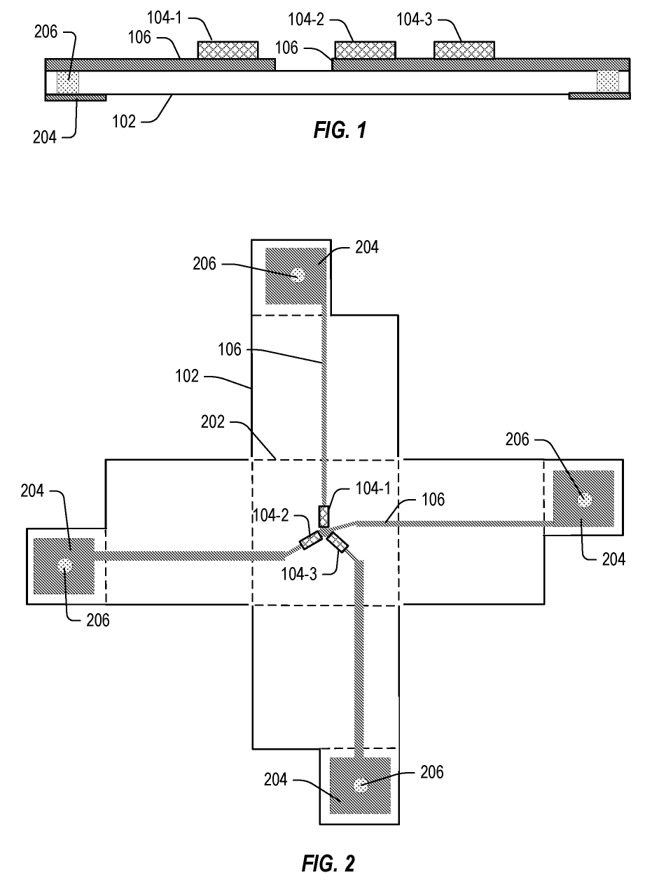

FIG. 1 is a cross-sectional view of a flexible support element 102 that comprises flexible electrical traces 106 and a plurality of LED chips 104-1, 104-2, and 104-3 (collectively referred to as LED chips 104) according to an embodiment of the present disclosure. It is to be appreciated that FIG. 1 is not to scale. At either end of the flexible support element 102, a thru via 206 can provide an electrical contact between the flexible electrical trace 106 and the electrical contact pads 204.

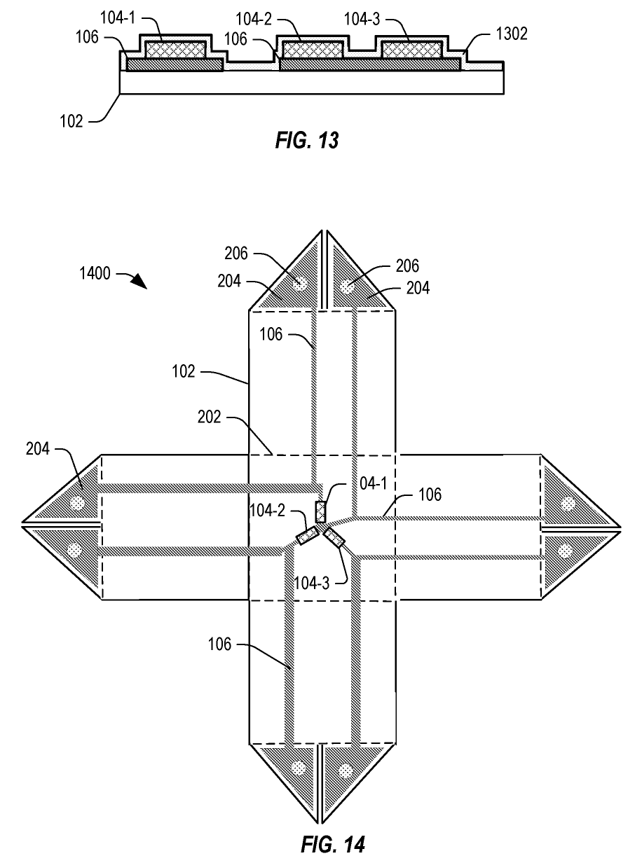

It is to be appreciated that FIGS. 1-12 show sequential steps in the formation of the LED package with the inverted color mixer as described herein. FIGS. 13 and 14-15,and 16-17, show different embodiments of the flexible support element 102 with regard to etch stops layers, and shapes of electrical contact pads 204, but are otherwise formed using the same process shown in FIGS. 1-12.

The flexible support element 102 can be plastic or some other flexible material such as cellulose acetate, polyimide, or polyethylene terephthalate (PET) and the flexible electrical traces 106 can be metal such as copper, gold, or some alloy thereof. The flexible electrical traces 106 can be deposited on the flexible support element 102 or be printed or mounted thereon. The LED chips 104 can emit light of different colors. In an embodiment, LED chips 104-1, 104-2, and 104-3 can be one or more of red, green, or blue, or other combinations of colors.

FIG. 2 is a top-down view of the flexible support element 102 of FIG. 1 according to an embodiment of the present disclosure.

The flexible support element 102 can include portions that are designed to be folded. In an embodiment, the flexible support element 102 can include seams 202 to facilitate folding along configured lines. The seams 202 can be formed by perforating the flexible support element 102 or can be formed by removing a layer of the flexible support element 102 or otherwise forming a line of thinner material so that when the flexible support element 102 is inserted into a mold, the flexible support element 102 would bend along predictable lines.

The flexible electrical traces 106 can connect to the electrodes of the LED chips 104 and provide traces to electrical contact pads 204, which are on the opposite sides of the flexible support element 102 but connected electrically by the thru vias 206. In the embodiment shown in FIG. 2, the flexible electrical traces 106 are on the top surface of the flexible support element 102, and the electrical contact pads 204 are on the back side of the flexible support element 102. Each of the LED chips 104-1, 104-2, and 104-3 have a respective electrode connected via the flexible electrical traces 106 to a respective electrical contact pad 204, and the other electrodes of each of LED chips 104-1, 104-2, and 104-3 are connected to a common flexible electrical trace 106 to a single electrical contact pad 204.

In the embodiment shown in FIG. 2, the LED chips 104-1, 104-2, and 104-3 are shown arrayed around a central point with rotational symmetry, while in other embodiments, they can be placed end to end, or side by side, or any other configuration.

FIG. 3 is a top-down view of a tray 302 of molds 304 according to an embodiment of the present disclosure.

In an embodiment, the flexible support element 102 could be part of a sheet of multiple flexible support elements 102, each with flexible electrical traces 106, LED chips 104, and electrical contact pads 204 formed thereon. There could be perforations or other means of separating individual flexible support elements 102 from each other.

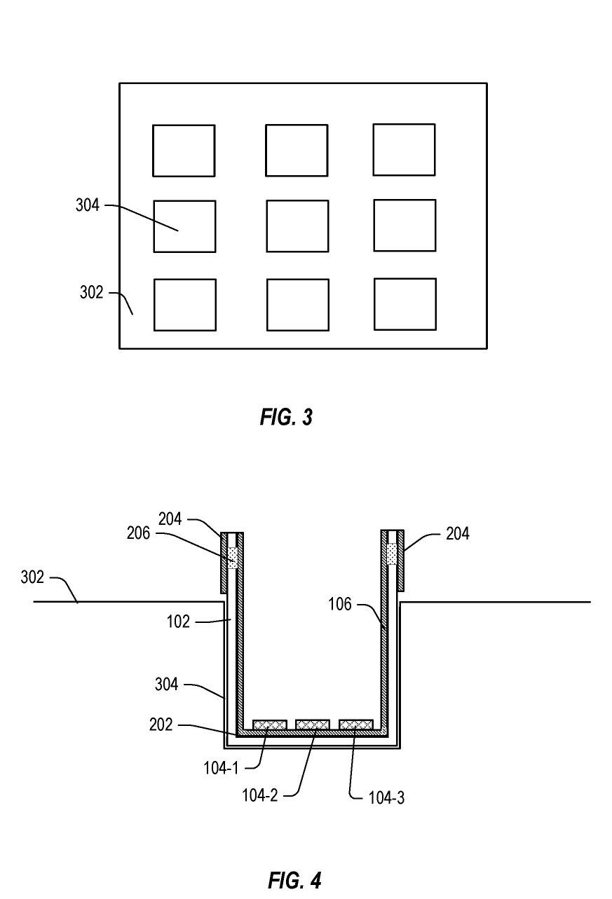

The sheet of flexible support elements 102 could be placed over the tray 302 of molds 304, and the flexible support elements 102 could be inserted into the molds 304 as shown in FIG. 4, which is a cross-sectional view of the flexible support element 102 inserted into a mold 304 in a step in the manufacturing process of an LED package according to an embodiment of the present disclosure.

The flexible support element 102 can be inserted into the mold 304 by the use of a plunger or other instrument, and the flexible support element 102 can fold along the seams 202 at the corners of the mold 304. The flexible support element 102 can be at the base of the mold 304 between the mold 304 and the flexible electrical trace 106 and LED chips 104-1, 104-2, and 104-3. The foldable portions of the flexible support element 102 that include the electrical contact pads 204 and thru vias 206 can extend above the top of the mold 304.

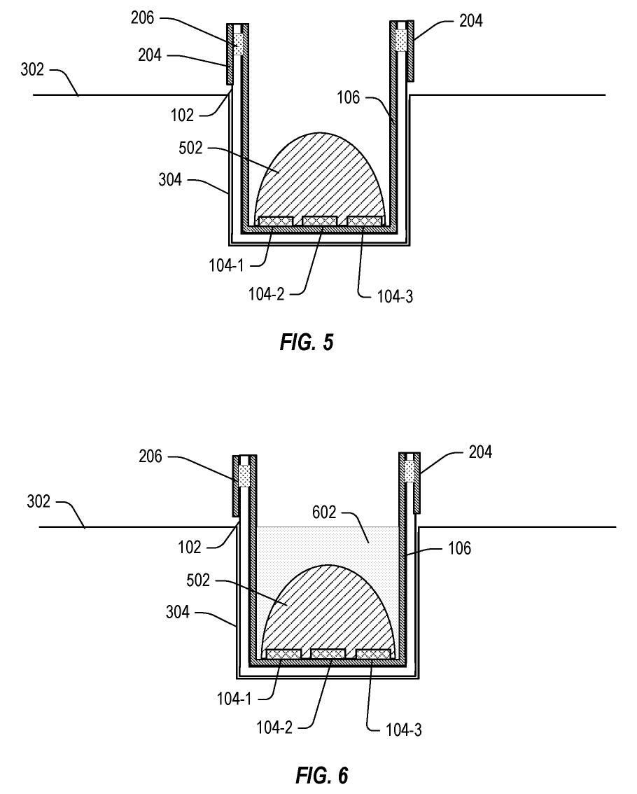

FIG. 5 is a cross-sectional view of the mold 304 and flexible support element 102 with a transparent dome 502 installed within the housing of the LED package according to an embodiment of the present disclosure.

The transparent dome 502 is formed after the flexible support element 102 is inserted into the mold 304. The transparent dome 502 can be formed via injection molding in some embodiments. In other embodiments, the transparent dome 502 can be preformed and then placed over the LED chips 104-1, 104-2, and 104-3, flexible electrical traces 106, and flexible support element 102. The transparent dome 502 forms the chamber of the inverted color mixer within which light emitted by the LED chips 104-1, 104-2, and 104-3 mixes before being emitted out of the LED package through gaps in the flexible electrical traces 106 beneath the LED chips 104. The transparent dome 502 can be formed from an epoxy that is rated for outdoor use.

FIG. 6 is a cross-sectional view of the mold 304 and flexible support element 102 with fill material 602 added according to an embodiment of the present disclosure.

The fill material 602 can be injected or inserted into the well of the mold 304 after the transparent dome 502 is formed. The fill material 602 can be white and may be silicone or a different type of epoxy than that which the transparent dome 502 is formed from. The fill material 602 provides a reflective surface off which light emitted from the LED chips 104 can reflect back into the transparent dome 502. The transparent dome 502 and the fill material 602 together form the inverted color mixer within the housing of the LED package formed by the sides of the flexible support element 102.

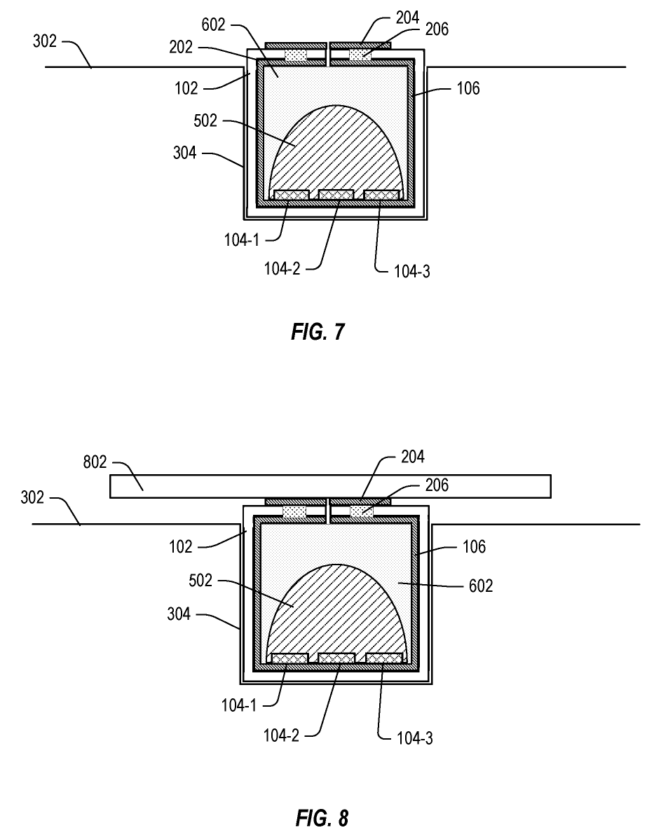

FIG. 7 is a cross-sectional view of the mold 304 and flexible support element 102 with the electrical contact pads 204 folded over the fill material 602 of the LED package according to an embodiment of the present disclosure.

After the fill material 602 is added, the portions of the flexible support element 102 that includes the electrical contact pads 204 can be folded over the fill material 602, where the seams 202 can facilitate the folding. The electrical contact pads 204 and flexible support element 102 can then enclose or partially enclose the fill material 602 and form the housing of the LED package. The electrical contact pads 204, since on the opposite sides of the flexible support element 102 from the flexible electrical traces 106, are, after folding over the fill material 602, on the outside of the LED package.

FIG. 8 is a cross-sectional view of a removal element 802 with an adhesive surface attached to the electrical contact pads 204 according to an embodiment of the present disclosure.

After the electrical contact pads 204 and portions of flexible support elements 102 are folded over the fill material 602 to form the housing of the LED package, a removal element 802 with an adhesive surface can be applied to the electrical contact pads 204, and then after the electrical contact pads 204 adhere to the adhesive surface of the removal element 802, the removal element 802 can be lifted or removed from the tray 302 that contains the mold 304 to remove the LED package from the mold 304.

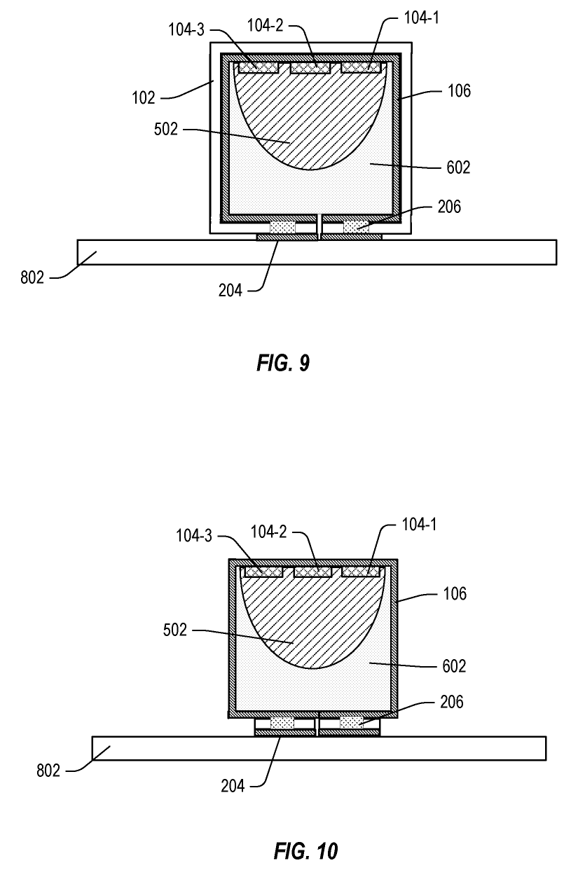

FIG. 9 is a cross-sectional view of the LED package after being removed from the mold 304 according to an embodiment of the present disclosure. After removal, the removal element 802 can be inverted and the LED package can stand on the removal element 802, attached via the electrical contact pads 204 to the removal element 802. Once removed from the mold 304, the flexible support element 102 comprising plastic (e.g., cellulose acetate, polyimide, or PET) can be on the outside of the LED package. At this point in the process, the plastic of the flexible support element 102 can be removed via plasma ashing or etching.

FIG. 10 is a cross-sectional view of the LED package after removing the plastic from the flexible support element 102 according to an embodiment of the present disclosure. In FIG. 10, once the plastic of the flexible support element 102 is removed, the flexible electrical traces 106 are on the outside of the LED package. It is to be appreciated that the flexible electrical traces 106 do not fully enclose the LED package, and that the fill material 602 is also on the external facing walls of the LED package. Similarly, on the top of the LED package, the portions of the transparent dome may be on the external surface of the LED package around the flexible electrical traces 106 contacting the electrodes of the LED chips 104.

FIG. 11 is a cross-sectional view of the LED package with an epoxy shell 1102 according to an embodiment of the present disclosure.

After the plastic of the flexible support element 102 is removed, the LED package can have an epoxy shell 1102 formed around the LED package. The epoxy shell 1102 can be of the same material that the transparent dome 502 is formed from and therefore be transparent. The epoxy shell 1102 can completely encase the LED package except for the interface with the electrical contact pads 204 on the opposite side of the LED package from the LED chips 104.

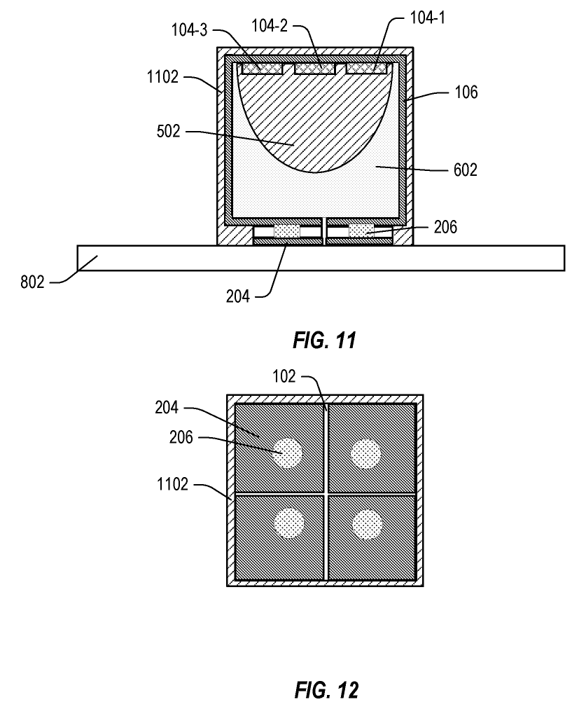

FIG. 12 is a top-down view of the LED package and the electrical contact pads 204 according to an embodiment of the present disclosure.

The thru vias 206 are depicted for reference only, and would not be visible from the top, as the electrical contact pads 204 are the external facing elements of the LED package, and the thru vias 206 connect the flexible electrical traces 106 through the plastic portion of the flexible support element 102 to the electrical contact pads 204. The electrical contact pads 204 are not in contact with each other, and are separated by gaps, showing the plastic of the flexible support element 102 between each of the electrical contact pads 204. In the embodiments shown in FIG. 12, three of the electrical contact pads 204 are connected to respective flexible electrical traces 106 coupled to respective electrodes of the LED chips 104-1, 104-2,and 104-3, while the fourth electrical contact pad 204 is coupled to the flexible electrical trace 106 that connects to the other electrode of each of the LED chips 104.

FIG. 13 is a cross-sectional view of another embodiment of the flexible support element 102 according to an embodiment of the present disclosure.

FIG. 13 shows an embodiment similar to that shown in FIG. 1, except for just showing the central part of the flexible support element 102 without the electrical contact pads 204 shown, except that there is an additional layer formed over the LED chips 104 and the flexible electrical traces 106 that is an etch stop layer 1302. The etch stop layer 1302 can in an embodiment be aluminum oxide (Al₂O₃) or silicon dioxide (SiO₂) or any other transparent dielectric layer. The etch stop layer 1302 can be a thin layer deposited onto the flexible support element 102 to prevent a specific etching process (e.g., the plasma ashing or plastic removal step) from reaching and damaging the underlying material.

FIG. 14 is a top-down view of another embodiment of the flexible support element according to an embodiment of the present disclosure.

FIG. 14 shows an embodiment similar to FIG. 2, except that instead of having four electrical contact pads 204, there are eight electrical contact pads 204, with two on each wing of the flexible support element 102, where each of the two electrical contact pads 204 are connected to different electrodes of the LED chips 104. The electrical contact pads 204 are connected to the flexible electrical traces 106 in such a way that after formation of the LED package, when looking at FIG. 15, which is the top down view of the LED package of the embodiment in FIG. 14 after the LED package is formed, each of the four corners comprises two of the electrical contact pads 204 that are connected to the same electrode. The benefit of this embodiment is that even if one of the flexible electrical traces 106 connected to each electrode of the LED chips 104 breaks, there is a redundancy with the other electrical contact pad 204 and flexible electrical trace 106 able to maintain an electrical connection.

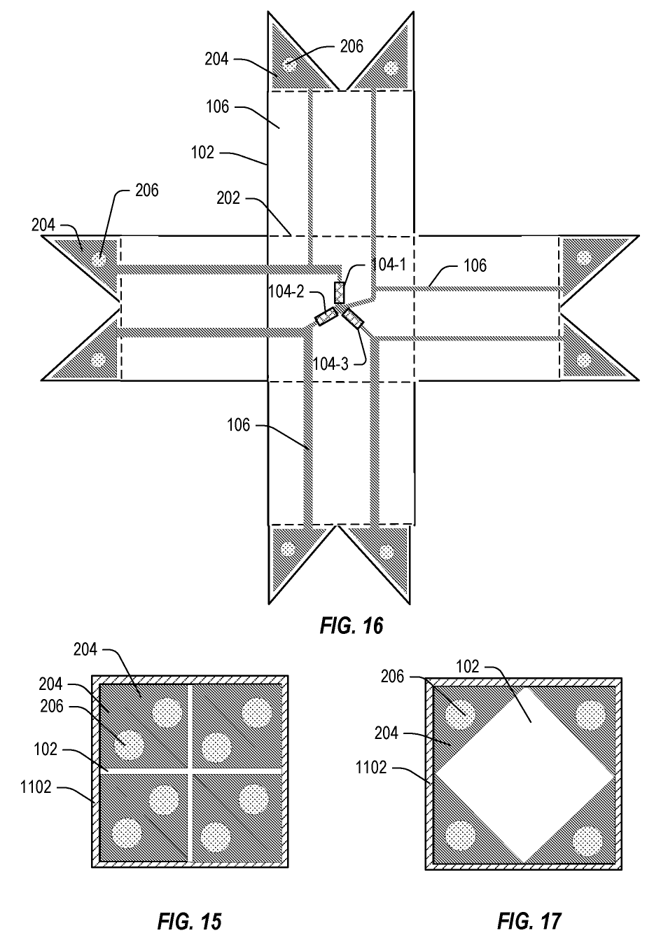

Different embodiments in FIGS. 16 and 17 accomplish a similar redundancy function, where in FIG. 16, the electrical contact pad triangles are oriented differently than in FIG. 14, such that after formation of the LED package, the top-down view in FIG. 17 shows that the electrical contact pads 204 stack on top of each other in each of the four corners at the top of the LED package.

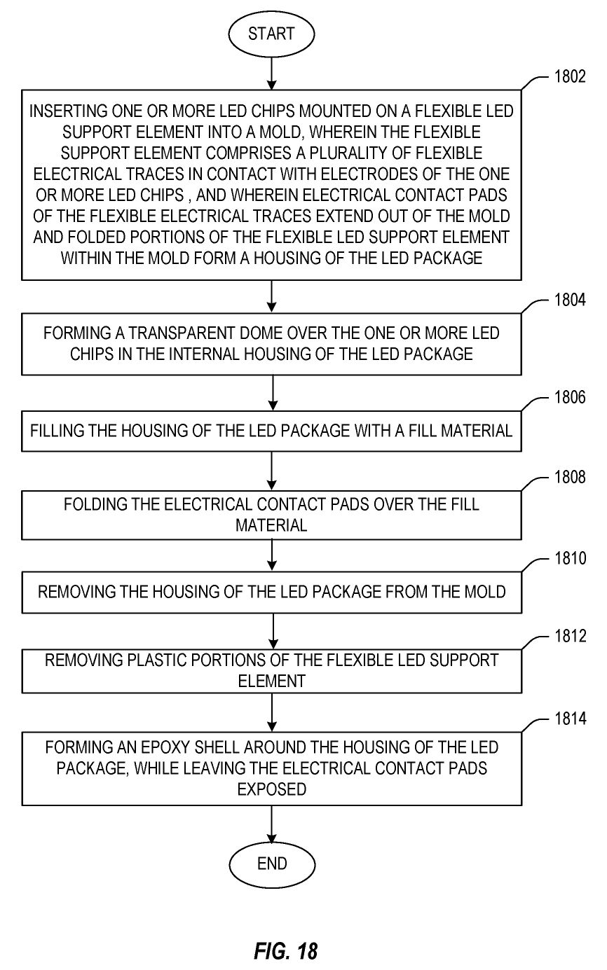

FIG. 18 is a flow chart of a method for forming an LED package according to an embodiment of the present disclosure.

The method in FIG. 18 starts at 1802, where the method includes inserting one or more LED chips mounted on a flexible support element into a mold, wherein the flexible support element comprises a plurality of flexible electrical traces in contact with electrodes of the one or more LED chips, and wherein electrical contact pads of the flexible electrical traces extend out of the mold and folded portions of the flexible support element within the mold form a housing of the LED package. In an embodiment, the flexible support element comprises an etch stop layer, wherein the one or more LED chips and the flexible electrical traces are between the etch stop layer and plastic portions of the flexible support element. In another embodiment, each respective electrode of the one or more LED chips is electrically connected to two or more electrical contact pads.

At 1804, the method includes forming a transparent dome over the one or more LED chips in the internal housing of the LED package. The transparent dome can be formed by injection molding or can be attached or mounted over the LED chips. The transparent dome can be formed from a transparent epoxy that is rated for outdoor use.

At 1806, the method includes filling the housing of the LED package with a fill material. In an embodiment, the fill material is a white epoxy or silicone. In an embodiment, the steps of 1804 and 1806 can be combined into a single step comprising forming an inverted color mixer over the one or more LED chips in the internal housing of the LED package, wherein the inverted color mixer comprises a transparent dome over the one or more LED chips and a fill material surrounding the transparent dome, wherein light emitted by the one or more LED chips exits the inverted color mixer via gaps in the flexible electrical traces.

At 1808, the method includes folding the electrical contact pads over the fill material.

At 1810, the method includes removing the housing of the LED package from the mold. The removing step can include attaching a removal element with an adhesive surface to the electrical contact pads and pulling the removal element away from the mold to remove the housing of the LED package from the mold.

At 1812, the method includes removing plastic portions of the flexible support element. In an embodiment, this can include at least one of etching the plastic portions or performing plasma ashing.

At 1814, the method includes forming an epoxy shell around the housing of the LED package, while leaving the electrical contact pads exposed. In an embodiment, the transparent dome and the epoxy shell comprise the same material. In another embodiment, the one or more LED chips are adjacent to an opposite face of the LED package as a face that comprises the electrical contact pads.

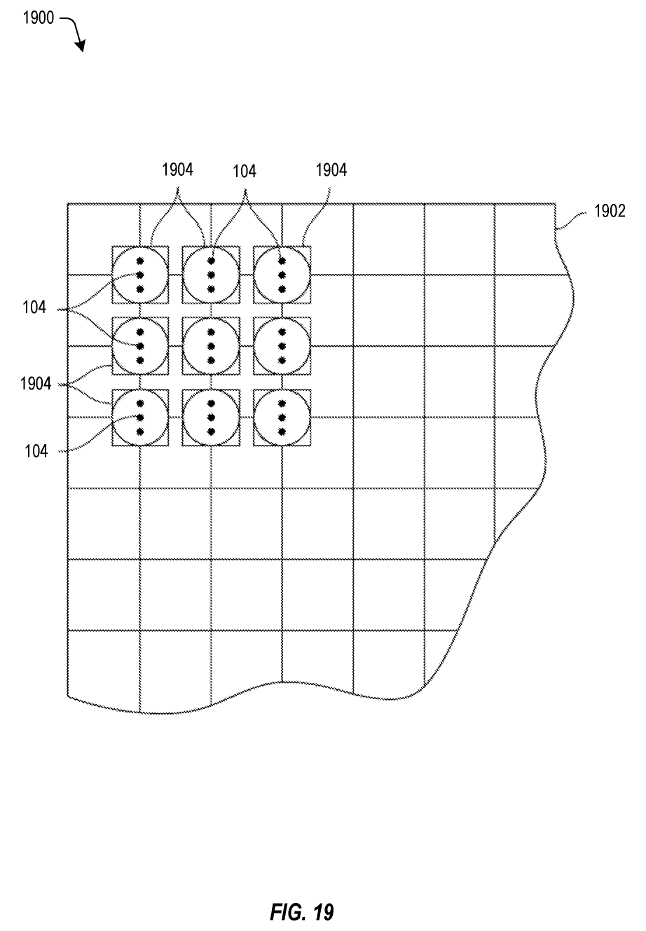

FIG. 19 is a schematic diagram of a portion of an LED device, such as a display screen including a large number of LED packages according to principles of the present disclosure.

FIG. 19 is a schematic diagram of a portion of an LED device 1900, such as a display screen, for example, an indoor and/or outdoor screen comprising, in general terms, a display panel including a driver printed circuit board (PCB) 1902 carrying a large number of surface-mount devices (SMDs) 1904 arranged in rows and columns, each SMD 1904 defining a pixel. Each SMD 1904 could be, for example, LED packages with inverted color mixers according to any of the embodiments described above with respect to FIGS. 1-17. Additionally, each SMD 1904 may represent a multiple chip embodiment of different colors, such as red-green-blue, for forming an LED pixel. With the integral color mixers for each SMD 1904 according to the principles described herein, the LED device 1900 may exhibit improved overall color uniformity across a variety of viewing angles. The SMDs 1904 are electrically connected to traces or pads on the PCB 1902 to respond to appropriate electrical signal processing and driver circuitry (not shown). While FIG. 19 depicts the LED chips 104 (e.g., 104-1, 104-2, and 104-3) in a linear arrangement within each LED package for the SMDs 1904, in other embodiments, the LED chips 104 may be arranged in different configurations.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A method for forming a light-emitting diode (LED) package, comprising:
inserting one or more LED chips mounted on a flexible support element into a mold, wherein the flexible support element comprises a plurality of flexible electrical traces in contact with electrodes of the one or more LED chips, and wherein electrical contact pads of the flexible electrical traces extend out of the mold and folded portions of the flexible support element within the mold form a housing of the LED package;
forming a transparent dome over the one or more LED chips in the housing of the LED package;
filling the housing of the LED package with a fill material;
folding the electrical contact pads over the fill material;
removing the housing of the LED package from the mold;
removing plastic portions of the flexible support element; and
forming an epoxy shell around the housing of the LED package, while leaving the electrical contact pads exposed.

2. The method of claim 1, wherein the removing plastic portions of the flexible support element comprises at least one of etching the plastic portions or performing plasma ashing.

3. The method of claim 1, wherein the transparent dome and the epoxy shell comprise the same material.

4. The method of claim 1, wherein the one or more LED chips are adjacent to an opposite face of the LED package as a face that comprises the electrical contact pads.

5. The method of claim 1, wherein light is emitted from the LED package through gaps in the flexible electrical traces out of a face adjacent to the one or more LED chips.

6. The method of claim 1, wherein the transparent dome and the fill material form an inverted color mixer within the housing of the LED package.

7. The method of claim 1, wherein the fill material is a white epoxy.

8. The method of claim 1, wherein the removing the housing of the LED package from the mold comprises:
attaching a removal element with an adhesive surface to the electrical contact pads; and
pulling the removal element away from the mold to remove the housing of the LED package from the mold.

9. The method of claim 1, wherein the flexible support element comprises an etch stop layer, wherein the one or more LED chips and the flexible electrical traces are between the etch stop layer and the plastic portions of the flexible support element.

10. The method of claim 9, wherein the etch stop layer is Al₂O₃ or SiO₂ or another transparent dielectric layer.

11. The method of claim 1, wherein each respective electrode of the one or more LED chips is electrically connected to two or more electrical contact pads.

12. A method for forming a light-emitting diode (LED) package, comprising:
inserting one or more LED chips mounted on a flexible support element into a mold, wherein the flexible support element comprises a plurality of flexible electrical traces in contact with electrodes of the one or more LED chips, and wherein electrical contact pads of the flexible electrical traces extend out of the mold and folded portions of the flexible support element within the mold form a housing of the LED package;
forming an inverted color mixer over the one or more LED chips in the housing of the LED package, wherein the inverted color mixer comprises a transparent dome over the one or more LED chips and a fill material surrounding the transparent dome, wherein light emitted by the one or more LED chips exits the inverted color mixer via gaps in the flexible electrical traces;
folding the electrical contact pads over the fill material;
removing the housing of the LED package from the mold;
removing plastic portions of the flexible support element; and
forming an epoxy shell around the housing of the LED package, while leaving the electrical contact pads exposed.

13. The method of claim 12, wherein the removing plastic portions of the flexible support element comprises at least one of etching the plastic portions or performing plasma ashing.

14. The method of claim 12, wherein the transparent dome and the epoxy shell comprise the same material.

15. The method of claim 12, wherein the fill material is a white epoxy.

16. The method of claim 12, wherein the one or more LED chips are adjacent to an opposite face of the LED package as a face that comprises the electrical contact pads.

17. The method of claim 12, wherein the removing the housing of the LED package from the mold comprises:
attaching a removal element with an adhesive surface to the electrical contact pads; and
pulling the removal element away from the mold to remove the housing of the LED package from the mold.

18. The method of claim 12, wherein the flexible support element comprises an etch stop layer, wherein the one or more LED chips and the flexible electrical traces are between the etch stop layer and the plastic portions of the flexible support element.

19. The method of claim 18, wherein the etch stop layer is Al₂O₃ or SiO₂ or another transparent dielectric layer.

20. The method of claim 12, wherein each respective electrode of the one or more LED chips is electrically connected to two or more electrical contact pads.
